(19) United States
(12) Patent Application Publication
(10) Pub. No.: US 2025/0185486 A1
(43) Pub. Date: Jun. 5, 2025

(54) Organic Light Emitting Diode Display Device and Head Mounted Display Device Comprising Same

(71) Applicant: LG Display Co., Ltd., Seoul (KR)

(72) Inventors: Hakmin Lee, Paju-si (KR); Heejin Kim, Gimpo-si (KR)

(21) Appl. No.: 18/909,829

(22) Filed: Oct. 8, 2024

(30) Foreign Application Priority Data
Dec. 4, 2023 (KR) 10-2023-0173423

(51) Int. Cl. H10K 59/80; G02B 27/01; H10K 59/35

(52) U.S. Cl. CPC H10K 59/80518; G02B 27/0172; H10K 59/35

(57) ABSTRACT

An organic light emitting diode display device presented herein includes a substrate including a first sub-pixel, a second sub-pixel, and a third sub-pixel, a first insulating layer on the substrate, a first reflective electrode on the first insulating layer in the first sub-pixel, a second insulating layer covering the first reflective electrode and on the first insulating layer, a second reflective electrode on the second insulating layer in the second sub-pixel, a third insulating layer covering the second reflective electrode and on the second insulating layer, a third reflective electrode on the third insulating layer in the third sub-pixel, and at least one corrugation formation layer under at least one of the first reflective electrode, the second reflective electrode, and the third reflective electrode, the at least one corrugation formation layer having a corrugated surface.

### CROSS-REFERENCE TO RELATED APPLICATION

This application claims priority from Republic of Korea Patent Application No. 10-2023-0173423, filed on Dec. 4, 2023, which is hereby incorporated by reference in its entirety.

### BACKGROUND

### Field

The present disclosure relates to an organic light emitting diode display device in which light extraction efficiency can be increased, and a head mounted display device including the same.

### Description of Related Art

Organic light emitting diode display devices as the self-luminous types have a wider viewing angle and a higher contrast ratio than liquid crystal display devices and are lighter and thinner and have low consumed power because they do not require a separate backlight. In addition, the organic light emitting diode display devices have the advantages of being capable of DC low voltage driving, having a fast response time, and especially having the inexpensive manufacturing cost.

Recently, head mounted display devices including the organic light emitting diode display device have been developed. A head mounted display (HMD) device is an image display device that is worn on a user's head in the form of glasses or a helmet and focuses on a distance near the user's eyes. The head mounted display device can implement virtual reality (VR) or augmented reality (AR). A high-resolution and small-sized organic light emitting diode display device is applied to the head mounted display device.

### SUMMARY

In an organic light emitting diode display device, light emitting layers that emit light of different colors, such as red, green, and blue, for each sub-pixel may be formed individually, or a light emitting layer that emits light of a single color such as white may be commonly formed on all sub-pixels.

When the light emitting layer that emits white light is formed on all sub-pixels, a separate mask for forming the light emitting layer for each sub-pixel is not required, and thus a problem due to misalignment of a mask process, etc. does not occur.

However, when the light emitting layer is configured to emit white light, a color filter should be additionally provided to implement different colors for each sub-pixel, and thus there is a disadvantage in that light emitted from the light emitting layer is absorbed by the color filter to reduce light efficiency.

Therefore, embodiments of the present disclosure are directed to a display device in which light extraction efficiency can be increased.

Embodiments of the present disclosure are directed to providing a display device in which light extraction efficiency can be increased.

The objects of the present disclosure are not limited to the above-described objects, and other objects that are not mentioned will be able to be clearly understood by those skilled in the art from the following description.

An organic light emitting diode display device according to one or more embodiments of the preset disclosure includes a substrate including a first sub-pixel, a second sub-pixel, and a third sub-pixel, a first insulating layer on the substrate, a first reflective electrode on the first insulating layer in the first sub-pixel, a second insulating layer covering the first reflective electrode and on the first insulating layer, a second reflective electrode on the second insulating layer in the second sub-pixel, a third insulating layer covering the second reflective electrode and on the second insulating layer, and a third reflective electrode on the third insulating layer in the third sub-pixel. In addition, at least one corrugation formation layer having a corrugated surface may be under at least one of the first reflective electrode, the second reflective electrode, and the third reflective electrode.

A head mounted display device according to one or more embodiments of the present disclosure includes a left-eye eyepiece, a right-eye eyepiece, a left-eye display device configured to provide a first image to the left-eye eyepiece, and a right-eye display device configured to provide a second image to the right-eye eyepiece. Each of the left-eye display device and the right-eye display device includes a substrate including a first sub-pixel, a second sub-pixel, and a third sub-pixel, a first insulating layer on the substrate, a first reflective electrode on the first insulating layer in the first sub-pixel, a second insulating layer covering the first reflective electrode and on the first insulating layer, a second reflective electrode on the second insulating layer in the second sub-pixel, a third insulating layer covering the second reflective electrode and on the second insulating layer, and a third reflective electrode on the third insulating layer in the third sub-pixel. In addition, at least one corrugation formation layer having a corrugated surface may be under at least one of the first reflective electrode, the second reflective electrode, and the third reflective electrode.

Detailed matters of other embodiments are included in a detailed description and accompanying drawings.

### BRIEF DESCRIPTION OF THE DRAWINGS

FIG. 1 is a schematic plan view of an organic light emitting diode display device according to one or more embodiments of the present disclosure.

FIG. 2 is a schematic cross-sectional view of the organic light emitting diode display device, which is a cross-sectional view along line 2-2 in FIG. 1 according to one or more embodiments of the present disclosure.

FIG. 3 is an enlarged view of area 3 in FIG. 2 according to one or more embodiments of the present disclosure.

FIG. 4 is a schematic cross-sectional view of a light emitting layer according to one or more embodiments of the present disclosure.

FIG. 5 is an enlarged view of area 5 in FIG. 2 according to one or more embodiments of the present disclosure.

FIG. 6 is a schematic cross-sectional view of the organic light emitting diode display device according to one or more embodiments of the present disclosure.

FIG. 7 is a schematic cross-sectional view of the organic light emitting diode display device according to one or more embodiments of the present disclosure.

FIG. 8 is a schematic cross-sectional view of the organic light emitting diode display device according to one or more embodiments of the present disclosure.

FIG. 9 is a schematic cross-sectional view of the organic light emitting diode display device according to one or more embodiments of the present disclosure.

FIG. 10 is a schematic plan view of an organic light emitting diode display device according to one or more embodiments of the present disclosure.

FIG. 11 is a schematic cross-sectional view of the organic light emitting diode display device, which is a cross-sectional view along line 11-11 in FIG. 10 according to one or more embodiments of the present disclosure.

FIG. 12 is an enlarged view of area 12 in FIG. 11 according to one or more embodiments of the present disclosure.

FIGS. 13A and 13B are views showing the spectrum and Δu‘v’ values, respectively according to a viewing angle of light emitted from a first sub-pixel (red sub-pixel) of the organic light emitting diode display device according to one or more embodiments of the present disclosure.

FIGS. 14A and 14B are views showing the spectrum and Δu‘v’ values, respectively according to a viewing angle of light emitted from a second sub-pixel (green sub-pixel) of the organic light emitting diode display device according to one or more embodiments of the present disclosure.

FIGS. 15A and 15B are views showing the spectrum and Δu‘v’ values, respectively according to a viewing angle of light emitted from a third sub-pixel (blue sub-pixel) of the organic light emitting diode display device according to one or more embodiments of the present disclosure.

FIGS. 16 to 18 show a head mounted display device according to one or more embodiments of the present disclosure.

### DETAILED DESCRIPTION

Advantages and features of the present disclosure and methods for achieving them will become clear with reference to embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes, sizes, ratios, angles, numbers, and the like disclosed in the drawings for describing the embodiments of the present disclosure are illustrative, the present disclosure is not limited to the illustrated items. The same reference number indicates the same components throughout the disclosure. In addition, in describing the present disclosure, when it is determined that the detailed description of a related known technology may unnecessarily obscure the gist of the present disclosure, detailed description thereof will be omitted. When terms “comprises,” “has,” “include,” and the like described in the present disclosure are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “under,” “next to,” or the like, one or more other parts may be positioned between the two parts unless the term “immediately” or “directly” is used.

Although terms such as first and second are used to describe various components, the components are not limited by the terms. The terms are only used to distinguish one component from another. Therefore, a first component described below may be a second component within the technical spirit of the present disclosure.

The same reference number indicates the same components throughout the disclosure.

The size and thickness of each component shown in the drawings are shown for convenience of description, and the present disclosure is not necessarily limited to the sizes and thicknesses of the components shown.

Features of various embodiments of the present disclosure can be partially or fully coupled or combined, and as can be fully understood by those skilled in the art, various technical interconnection and operations are possible, and the embodiments may be implemented independently of each other and implemented together in combination thereof.

Hereinafter, an organic light emitting diode display device and a head mounted display device according to embodiments of the present disclosure will be described in detail with reference to the accompanying drawings.

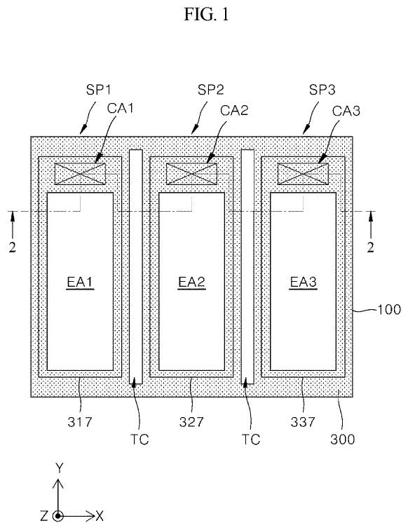

FIG. 1 is a schematic plan view of an organic light emitting diode display device according to one or more embodiments of the present disclosure. In the organic light emitting diode display device according to one or more embodiments of the present disclosure, a plurality of sub-pixels SP1, SP2, and SP3 are disposed in a matrix form, but only three sub-pixels SP1, SP2, and SP3 are shown in FIG. 1.

Referring to FIG. 1, the organic light emitting diode display device according to one or more embodiments of the present disclosure includes a plurality of anode electrodes 317, 327, and 337, a trench TC, and a bank 300.

For example, the plurality of sub-pixels SP1, SP2, and SP3 arranged in an X-axis direction are provided on a substrate 100.

A plurality of emission areas EA1, EA2, and EA3 corresponding to the plurality of sub-pixels SP1, SP2, and SP3 are provided. The first sub-pixel SP1 has the first emission area EA1, the second sub-pixel SP2 has the second emission area EA2, and the third sub-pixel SP3 has the third emission area EA3.

The plurality of emission areas EA1, EA2, and EA3 are defined by the bank 300. Areas exposed without covered by the bank 300 become the plurality of emission areas EA1, EA2, and EA3.

A plurality of anode electrodes 317, 327, and 337 corresponding to the plurality of sub-pixels SP1, SP2, and SP3 are provided. The first anode electrode 317 may be disposed in the first sub-pixel SP1, the second anode electrode 327 may be formed in the second sub-pixel SP2, and the third anode electrode 337 may be disposed in the third sub-pixel SP3. The first to third anode electrodes 317, 327, and 337 may be spaced apart from each other.

A portion of the first anode electrode 317 not covered by the bank 300 can be defined as the first emission area EA1. The first anode electrode 317 of the first sub-pixel SP1 may be connected to at least one transistor disposed on the substrate 100 through a first contact area CA1.

A portion of the second anode electrode 327 not covered by the bank 300 can be defined as the second emission area EA2. The second anode electrode 327 of the second sub-pixel SP2 may be connected to at least one transistor disposed on the substrate 100 through a second contact area CA2.

A portion of the third anode electrode 337 not covered by the bank 300 can be defined as the third emission area EA3. The third anode electrode 337 of the third sub-pixel SP3 may be connected to at least one transistor disposed on the substrate 100 through a third contact area CA3.

A trench TC extending in a Y-axis direction is formed in boundary areas between the plurality of sub-pixels SP1, SP2, and SP3. The trench TC may be formed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

A length of the trench TC in the Y-axis direction may be greater than lengths of the plurality of emission areas EA1, EA2, and EA3. The length of the trench TC in the Y-axis direction may be greater than or equal to lengths of the plurality of anode electrodes 317, 327, and 337.

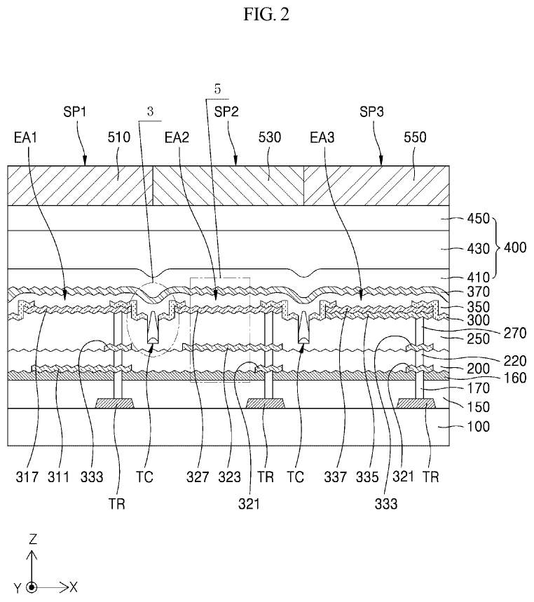

FIG. 2 is a schematic cross-sectional view of the organic light emitting diode display device, which is a cross-sectional view along line 2-2 in FIG. 1 according to one or more embodiments of the present disclosure.

Referring to FIG. 2, the organic light emitting diode display device according to one or more embodiments of the present disclosure may include the substrate 100, a driving transistor TR, first to third insulating layers 150, 200, 250, a first corrugation formation layer 160, first to third reflective electrodes 311, 323, and 335, first and second contact electrodes 321 and 333, the first to third anode electrodes 317, 327, and 337, the bank 300, a light emitting layer 350, a cathode electrode 370, the trench TC, an encapsulation layer 400, and first to third color filters 510, 530, and 550.

The organic light emitting diode display device according to one or more embodiments of the present disclosure may be implemented in a so-called top emission type in which light emitted from the light emitting layer 350 is emitted upward.

The substrate 100 may be made of a semiconductor material such as a silicon wafer. In one or more embodiments, the substrate 100 may be made of glass or plastic.

For example, the first sub-pixel SP1, the second sub-pixel SP2, and the third sub-pixel SP3 arranged in the X-axis direction are provided on the substrate 100. The first sub-pixel SP1 may emit red light, the second sub-pixel SP2 may emit green light, and the third sub-pixel SP3 may emit blue light. The arrangement order and direction of the sub-pixels SP1, SP2, and SP3 may be changed in any of various ways.

A driving circuit including various signal lines, thin film transistors, capacitors, etc. is provided on the substrate 100 for each of the sub-pixels SP1, SP2, and SP3. Signal lines may include gate lines, data lines, power lines, and reference lines, and transistors may include a switching transistor, a driving transistor TR, and a sensing thin film transistor. For example, the switching transistor, the driving transistor TR, and the sensing thin film transistor may be formed on the substrate 100 using a CMOS process.

The switching transistor is switched according to the gate signal supplied to the gate line to supply the data voltage supplied from the data line to the driving transistor.

The driving transistor TR is switched according to the data voltage supplied from the switching transistor to generate a data current from the power supplied from the power line and supply the data current to the anode electrodes 317, 327, and 337.

The sensing transistor serves to sense a threshold voltage difference of the driving transistor, which causes the degradation of image quality and supplies a current of the driving transistor to the reference line in response to a sensing control signal supplied from the gate line or a separate sensing line.

The capacitor serves to maintain the data voltage supplied to the driving transistor TR for one frame, and electrodes of the capacitor may be connected to a gate terminal and source terminal of the driving transistor TR, respectively.

The first insulating layer 150 may be disposed on the substrate 100. The first insulating layer 150 may be made of an inorganic insulating material or an organic insulating material. The first insulating layer 150 may cover transistors including driving transistors TR, various signal lines, capacitors, etc. disposed on the substrate 100.

The first corrugation formation layer 160 having a corrugated surface may be disposed on the first insulating layer 150. Any material having the corrugated surface may be used for the first corrugation formation layer 160, but the first corrugation formation layer 160 may be made of, for example, tetraphenylethylene (TPE). The tetraphenylethylene (TPE) may be formed by a deposition process, and a surface of the tetraphenylethylene (TPE) formed by the deposition process has the characteristic having corrugation.

In one or more embodiments, the first corrugation formation layer 160 may be formed by performing a dry etching process or a wet etching process after forming an inorganic insulating material or an organic insulating material on the first insulating layer 150.

The first reflective electrode 311 and the first contact electrodes 321 may be disposed on the first corrugation formation layer 160. The first reflective electrode 311 may be disposed in the first sub-pixel SP1, and the first contact electrode 321 may be disposed in each of the second sub-pixel SP2 and the third sub-pixel SP3. Since the first reflective electrode 311 and the first contact electrodes 321 are formed on an upper surface of the first corrugation formation layer 160 having corrugation, upper surfaces of the first reflective electrode 311 and the first contact electrodes 321 may also have corrugation. In one or more embodiments, an additional insulating layer may be disposed on the first corrugation formation layer 160, and the first reflective electrode 311 and the first contact electrodes 321 may be disposed on the additional insulating layer.

First contact vias 170 may be disposed to pass through the first corrugation formation layer 160 and the first insulating layer 150. In the first to third sub-pixels SP1, SP2, and SP3, the first reflective electrode 311 and the first contact electrodes 321 may each be connected to the driving transistor TR through the first contact vias 170 passing through the first corrugation formation layer 160 and the first insulating layer 150.

After the first contact vias 170 passing through the first corrugation formation layer 160 and the first insulating layer 150 are first formed, the first reflective electrode 311 and the first contact electrodes 321 are formed on the first insulating layer 150.

In one or more embodiments, the first reflective electrode 311 and the first contact via 170 may be formed integrally in the first sub-pixel SP1. The first contact electrode 321 and the first contact via 170 may be formed integrally in the second sub-pixel SP2. The first contact electrode 321 and the first contact via 170 may be formed integrally in the third sub-pixel SP3.

The first reflective electrode 311 and the first contact electrodes 321 may be made of a metal material with high reflectivity, such as silver (Ag), a silver alloy, aluminum (Al), or an aluminum alloy. The first contact via 170 may contain a metal material.

The second insulating layer 200 may be disposed on the first corrugation formation layer 160, and the second insulating layer 200 may cover the first reflective electrode 311 and the first contact electrodes 321. Since the second insulating layer 200 is formed on the upper surface of the first corrugation formation layer 160 having corrugation and the upper surfaces of the first reflective electrode 311 and the first contact electrodes 321 that have corrugation, an upper surface of the second insulating layer 200 may also have corrugation.

The second insulating layer 200 may be made of an inorganic insulating material or an organic insulating material.

The second reflective electrode 323 and the second contact electrodes 333 may be disposed on the second insulating layer 200.

The second reflective electrode 323 may be disposed in the second sub-pixel SP2, and the second contact electrode 333 may be disposed in each of the first sub-pixel SP1 and the third sub-pixel SP3. Since the second reflective electrode 323 and the second contact electrodes 333 are formed on an upper surface of the second insulating layer 200 having corrugation, upper surfaces of the second reflective electrode 323 and the second contact electrodes 333 may also have corrugation.

Second contact vias 220 may be disposed to pass through the second insulating layer 200.

In the first sub-pixel SP1, the second contact electrode 333 may be connected to the first reflective electrode 311 through the second contact via 220 passing through the second insulating layer 200. In the second sub-pixel SP2, the second reflective electrode 323 may be connected to the first contact electrode 321 through the second contact via 220 passing through the second insulating layer 200. In the third sub-pixel SP3, the second contact electrode 333 may be connected to the first contact electrode 321 through the second contact via 220 passing through the second insulating layer 200.

The second reflective electrode 323 and the second contact electrodes 333 may be made of a metal material with high reflectivity, such as silver (Ag), a silver alloy, aluminum (Al), or an aluminum alloy. The second contact via 220 may contain a metal material.

After the second contact vias 220 passing through the second insulating layer 200 are first formed, the second reflective electrode 323 and the second contact electrode 333 may be formed on the second insulating layer 200.

In one or more embodiments, the second contact electrode 333 and the second contact via 220 may be formed integrally in the first sub-pixel SP1. The second reflective electrode 323 and the second contact via 220 may be formed integrally in the second sub-pixel SP2. The second contact electrode 333 and the second contact via 220 may be formed integrally in the third sub-pixel SP3.

The third insulating layer 250 may be disposed on the second insulating layer 200, and the third insulating layer 250 may cover the second reflective electrode 323 and the second contact electrodes 333. Since the third insulating layer 250 is formed on the upper surface of the second insulating layer 200 having corrugation and the upper surfaces of the second reflective electrode 323 and the second contact electrodes 333 that have corrugation, an upper surface of the third insulating layer 250 may also have corrugation.

The third insulating layer 250 may be made of an inorganic insulating material or an organic insulating material.

The first anode electrode 317, the second anode electrode 327, the third reflective electrode 335, the third anode electrode 337 may be disposed on the third insulating layer 250. The first anode electrode 317 may be disposed in the first sub-pixel SP1, the second anode electrode 327 may be disposed in the second sub-pixel SP2, and the third reflective electrode 335 and the third anode electrode 337 may be disposed in the third sub-pixel SP3.

The third reflective electrode 335 and the third anode electrode 337 may be in contact with each other and the third anode electrode 337 may be disposed on the third reflective electrode 335 in the third sub-pixel SP3.

Since the first anode electrode 317, the second anode electrode 327, the third reflective electrode 335, and the third anode electrode 337 are formed on the upper surface of the third insulating layer 250 having corrugation, upper surfaces of the first anode electrode 317, the second anode electrode 327, the third reflective electrode 335, and the third anode electrode 337 may have corrugation.

Third contact vias 270 may be disposed to pass through the third insulating layer 250.

In the first sub-pixel SP1, the first anode electrode 317 may be connected to the second contact electrode 333 through the third contact via 270 passing through the third insulating layer 250. In the second sub-pixel SP2, the second anode electrode 327 may be connected to the second reflective electrode 323 through the third contact via 270 passing through the third insulating layer 250. In the third sub-pixel SP3, the third reflective electrode 335 may be connected to the second contact electrode 333 through the third contact via 270 passing through the third insulating layer 250.

In one or more embodiments, instead of the third reflective electrode 335 and the third anode electrode 337 being in contact with each other, an additional insulating layer may be further disposed on the third reflective electrode 335, and the first to third anode electrodes 317, 327, and 337 may be disposed on the additional insulating layer. In this case, the third reflective electrode 335 and the third anode electrode 337 may be connected through an additional contact via passing through the additional insulating layer.

The third reflective electrode 335 may be made of a metal material with high reflectivity, such as silver (Ag), a silver alloy, aluminum (Al), or an aluminum alloy. The third contact via 270 may contain a metal material. The first to third anode electrodes 317, 327, and 337 may be made of a transparent conductive material such as ITO or IZO that may transmit light.

The first to third anode electrodes 317, 327, and 337 may each be electrically connected to the source terminal or drain terminal of the driving transistor disposed on the substrate 100.

The bank 300 may be disposed to cover edge areas of the first to third anode electrodes 317, 327, and 337 on the third insulating layer 250. Portions of upper surfaces of the first to third anode electrodes 317, 327, and 337 exposed without covered by the bank 300 become emission areas. An upper surface of the bank 300 disposed on the third insulating layer 250 and the first to third anode electrodes 317, 327, and 337 may also have corrugation.

The bank 300 may be made of an inorganic insulating material. In one or more embodiments, the bank 300 may be made of an organic insulating material.

The trench TC having a concave structure is formed in the bank 300 and the third insulating layer 250. The trench TC may pass through the bank 300 in the boundary areas between the sub-pixels SP1, SP2, and SP3 and extend to a predetermined area of the third insulating layer 250. Therefore, the trench TC may be formed through a process of removing the bank 300 and the predetermined area of the third insulating layer 250. In one or more embodiments, the trench TC may extend to the inside of the second insulating layer 200 under the third insulating layer 250.

The trench TC is used to disconnect at least a portion of the light emitting layer 350. By disconnecting at least a portion of the light emitting layer 350 in the trench TC, it is possible to prevent charges from moving between the neighboring sub-pixels SP1, SP2, and SP3 through the light emitting layer 350, thereby preventing the generation of a leakage current between the neighboring sub-pixels SP1, SP2, and SP3.

The light emitting layer 350 may be disposed in the emission areas EA1, EA2, and EA3 of the sub-pixels SP1, SP2, and SP3 and the boundary areas between the sub-pixels SP1, SP2, and SP3. The light emitting layer 350 may be disposed on the first to third anode electrodes 317, 327, and 337 and the bank 300 and may also be disposed inside and above the trench TC. An upper surface of the light emitting layer 350 disposed on the first to third anode electrodes 317, 327, and 337 and the bank 300 may also have corrugation.

The light emitting layer 350 may be provided to emit white (W) light. To this end, the light emitting layer 350 may include a plurality of stacks that emit light of different colors.

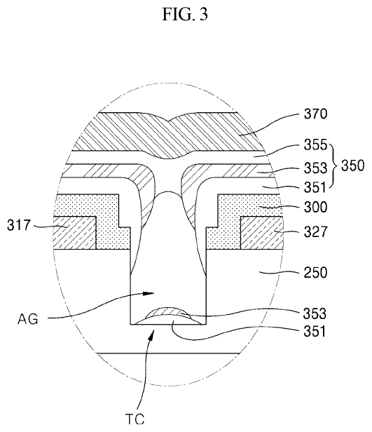

Referring to FIG. 3, the light emitting layer 350 may include a first stack 351, a second stack 355, and a charge generation layer CGL 353 provided between the first stack 351 and the second stack 355.

The light emitting layer 350 may be disposed inside and above the trench TC. When the light emitting layer 350 is disposed inside the trench TC, at least a portion of the light emitting layer 350 may be disconnected, thereby preventing the generation of the leakage current between the adjacent sub-pixels SP1, SP2, and SP3.

The first stack 351 may be disposed on side surfaces and a lower surface of the trench TC. In this case, a portion of the first stack 351 formed on the side surfaces of the trench TC and a portion of the first stack 351 formed on the lower surface of the trench TC are not connected. In addition, the portion of the first stack 351 formed on one side surface, such as a left side surface, of the trench TC and a portion of the first stack 351 formed on the other side surface, such as a right side surface, of the trench TC are not connected. Therefore, charges may not move between the sub-pixels SP1, SP2, and SP3 disposed adjacent to each other with the trench TC interposed therebetween through the first stack 351.

In addition, the charge generation layer 353 may be disposed on the first stack 351. In this case, the charge generation layer 353 may not extend to the inside of the trench TC and may be disposed only above the trench TC. In addition, the charge generation layer 353 may also be disposed on the first stack 351 disposed on the lower surface of the trench TC.

In this case, a portion of the charge generation layer 353 formed on one side surface, such as the left side surface, of the trench TC and a portion of the charge generation layer 353 formed on the other side surface, such as the right side surface, of the trench TC are not connected. Therefore, charges may not move between the sub-pixels SP1, SP2, and SP3 disposed adjacent to each other with the trench TC interposed therebetween through the charge generation layer 353.

In addition, the second stack 355 may be connected between the sub-pixels SP1, SP2, and SP3 disposed adjacent to each other with the trench TC interposed therebetween on the charge generation layer 353. Therefore, charges may move between the sub-pixels SP1, SP2, and SP3 disposed adjacent to each other with the trench TC interposed therebetween through the second stack 355. However, by appropriately adjusting the shape of the trench TC and the deposition process of the light emitting layer 350, the second stack 355 may also be disconnected between the sub-pixels SP1, SP2, and SP3 disposed adjacent to each other with the trench TC interposed therebetween. In particular, a lower portion of the second stack 355 adjacent to the charge generation layer 353 may be disconnected in the areas between the sub-pixels SP1, SP2, and SP3.

An air gap AG is formed in the trench TC by the structures of the first stack 351, the charge generation layer 353, and the second stack 355. The air gap AG can be defined by the third insulating layer 250 and the light emitting layer 350. The air gap AG provided under the light emitting layer 350 can be defined by the third insulating layer 250, the first stack 351, the charge generation layer 353, and the second stack 355. The air gap AG may extend from the inside of the trench TC to the top of the trench TC.

The charge generation layer 353 has greater conductivity than the first stack 351 and the second stack 355. The charge generation layer 353 may include an n-type charge generation layer located adjacent to the first stack 351 and a p-type charge generation layer located adjacent to the second stack 355. This n-type charge generation layer may be an organic layer in which an organic host material capable of the electron transport ability is doped with an alkali metal such as Li, Na, K, or Cs or an alkaline earth metal such as Mg, Sr, Ba, or Ra, and the p-type charge generation layer may be made of an organic host material capable of the hole transport ability doped with a dopant.

As described above, since the n-type charge generation layer constituting the charge generation layer 353 may be made of a metal material, the n-type charge generation layer has greater conductivity than the first stack 351 and the second stack 355. Therefore, charges between the sub-pixels SP1, SP2, and SP3 disposed adjacent to each other are mainly moved through the charge generation layer 353.

In the organic light emitting diode display device according to one or more embodiments of the present disclosure, by forming a portion of the light emitting layer 350 to be disconnected in the trench TC when the light emitting layer 350 is formed in the trench TC, in particular, by forming the first stack 351 and the charge generation layer 353 to be disconnected in the trench TC, it is possible to prevent the generation of the leakage current between the adjacent sub-pixels SP1, SP2, and SP3. The trench TC and the surrounding components thereof according to FIG. 3 may also be applied to various embodiments to be described below.

The cathode electrode 370 is formed on the light emitting layer 350. Like the light emitting layer 350, the cathode electrode 370 may also be disposed in the emission areas EA1, EA2, and EA3 of the sub-pixels SP1, SP2, and SP3 and the boundary areas between the sub-pixels SP1, SP2, and SP3. The cathode electrode 370 is a common layer and may also be formed above the bank 300 and the trench TC. An upper surface of the cathode electrode 370 disposed on the light emitting layer 350 may also have corrugation.

The cathode electrode 370 may be made of a semi-transparent conductive material. The cathode electrode 370 may be made of a semi-transparent metal material such as magnesium (Mg), silver (Ag), or an alloy of magnesium (Mg) and silver (Ag). The cathode electrode 370 may be formed in the form of a thin film having the thickness of several nanometers to tens of nanometers. Therefore, it is possible to obtain the micro cavity effect as light is repeatedly reflected and re-reflected between the cathode electrode 370 and the first to third reflective electrodes 311, 323, and 335.

According to one or more embodiments of the present disclosure, since the first distance between the first reflective electrode 311 and the cathode electrode 370 in the first sub-pixel SP1, the second distance between the second reflective electrode 323 and the cathode electrode 370 in the second sub-pixel SP2, and the third distance between the third reflective electrode 335 and the cathode electrode 370 in the third sub-pixel SP3 may all be configured differently, it is possible to increase light extraction efficiency of light of different colors, such as red, green, and blue light in the sub-pixels SP1, SP2, and SP3 by the micro cavity effect.

The encapsulation layer 400 is formed on the cathode electrode 370 to prevent the permeation of external moisture into the light emitting layer 350. The encapsulation layer 400 may include a first inorganic encapsulation layer 410 disposed on the cathode electrode 370, an organic encapsulation layer 430 disposed on the first inorganic encapsulation layer 410, and a second inorganic encapsulation layer 450 disposed on the organic encapsulation layer 430. The first and second inorganic encapsulation layers 410 and 450 may each be selected from aluminum oxide (AlₓO_{y}), silicon oxide (SiOₓ), silicon nitride (SiNₓ), silicon oxynitride (SiON), etc. The first and second inorganic encapsulation layers 410 and 450 may each have a refractive index of 1.7 to 1.9. In one or more embodiments, a capping layer may be further disposed between the cathode electrode 370 and the encapsulation layer 400. The capping layer can protect the light emitting layer 350 and the cathode electrode 370 and allow light emitted in the light emitting layer 350 to be efficiently emitted to the outside. The capping layer may include an organic film, an inorganic film, or a stacking structure thereof.

The color filters 510, 530, and 550 may be disposed on the encapsulation layer 400. The red color filter 510 overlapping the first emission area EA1 may be provided in the first sub-pixel SP1, the green color filter 530 overlapping the second emission area EA2 may be provided in the second sub-pixel SP2, and the blue color filter 550 overlapping the third emission area EA3 may be provided in the third sub-pixel SP3.

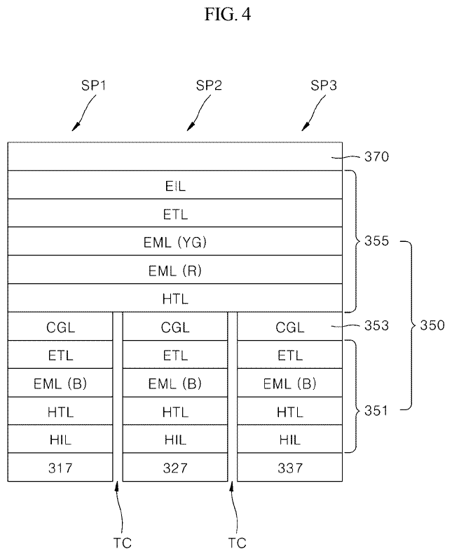

FIG. 4 is a schematic cross-sectional view of light emitting layers disposed in sub-pixels according to one or more embodiments of the present disclosure.

Referring to FIG. 4, the first anode electrode 317 is disposed in the first sub-pixel SP1, the second anode electrode 327 is disposed in the second sub-pixel SP2, and the third anode electrode 337 is disposed in the third sub-pixel SP3.

The light emitting layer 350 is disposed on the first to third anode electrodes 317, 327, and 337. The light emitting layer 350 includes the first stack 351, the second stack 355, and the charge generation layer CGL 353.

The first stack 351 may be formed in a structure in which a hole injecting layer HIL, a hole transporting layer HTL, a blue emitting layer EML(B), and an electron transporting layer ETL are stacked sequentially. The first stack 351 is disconnected in the boundary areas between the sub-pixels SP1, SP2, and SP3, that is, the trench TC areas.

The charge generation layer CGL 353 serves to supply charges to the first stack 351 and the second stack 355. The charge generation layer CGL 353 may include an n-type charge generation layer for supplying electrons to the first stack 351 and a p-type charge generation layer for supplying holes to the second stack 355. As described above, the n-type charge generation layer may include a metal material as a dopant. The charge generation layer 353 is disconnected in the boundary areas between the sub-pixels SP1, SP2, and SP3, that is, the trench TC areas.

The second stack 355 may be provided on the charge generation layer CGL 353 and formed in a structure in which the hole transporting layer HTL, a red emitting layer EML(R), a yellow green emitting layer EML(YG), the electron transporting layer ETL, and the electron injecting layer EIL are stacked sequentially. The stacking order of the red emitting layer EML(R) and the yellow green emitting layer EML(YG) may be changed.

The second stack 355 may be disposed to be connected between the sub-pixels SP1, SP2, and SP3. However, as described above, the lower portion of the second stack 355 may be disconnected in the boundary areas between the sub-pixels SP1, SP2, and SP3, that is, the trench TC areas. For example, the hole transporting layer HTL of the second stack 355 may be disconnected, or the hole transporting layer HTL and the red emitting layer EML(R) of the second stack 355 may be disconnected. For example, the hole transporting layer HTL, the red emitting layer EML(R), and the yellow green emitting layer EML(YG) of the second stack 355 may be disconnected.

The cathode electrode 370 is disposed on the light emitting layer 350. The cathode electrode 370 may be formed to be connected between the sub-pixels SP1, SP2, and SP3.

The light emitting layer 350 of FIG. 4 emits white light in a combination of the blue emitting layer EML(B) of the first stack 351 and the red emitting layer EML(R) and the yellow green emitting layer EML(YG) of the second stack 355.

In one or more embodiments, the second stack 355 may include only the yellow green emitting layer EML(YG). In this case, white light is emitted in a combination of the blue emitting layer EML(B) of the first stack 351 and the yellow green emitting layer EML(YG) of the second stack 355.

In one or more embodiments, the green emitting layer EML(G) may be formed instead of the yellow green emitting layer EML(YG) of the second stack 355. In this case, the light emitting layer 350 emits white light in a combination of the blue emitting layer EML(B) of the first stack 351 and the red emitting layer EML(R) and green emitting layer EML(G) of the second stack 355.

In one or more embodiments, the first stack 351 may include the red emitting layer EML(R) and the yellow green emitting layer EML(YG), and the second stack 355 may include the blue emitting layer EML(B). In one or more embodiments, the first stack 351 may include the red emitting layer EML(R) and the green emitting layer EML(G), and the second stack 355 may include the blue emitting layer EML(B).

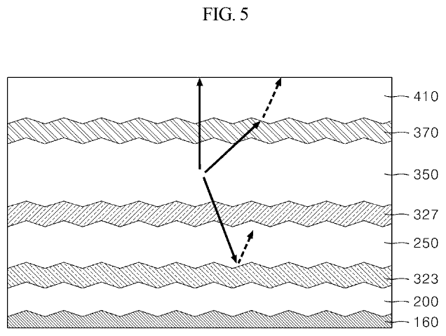

FIG. 5 is an enlarged view of area 5 in FIG. 2 according to one or more embodiments of the present disclosure. FIG. 5 is an enlarged view of a portion of the second sub-pixel SP2 to describe an increase in light extraction efficiency in the organic light emitting diode display device according to one or more embodiments of the present disclosure.

Referring to FIG. 5, the first corrugation formation layer 160 is disposed under the second insulating layer 200 in the second sub-pixel SP2 so that the lower and upper surfaces of the second insulating layer 200, the lower and upper surfaces of the second reflective electrode 323, the lower and upper surfaces of the third insulating layer 250, the lower and upper surfaces of the second anode electrode 327, the lower and upper surfaces of the light emitting layer 350, the lower and upper surfaces of the cathode electrode 370, and the lower surface of the first inorganic encapsulation layer 410 may have corrugation.

A portion of the light emitted from the light emitting layer 350 may be lost by a waveguide mode, the SPP (Surface Plasmon Polariton) mode, etc.

Although some of the light emitted from the light emitting layer 350 may be emitted through the cathode electrode 370, some of the light emitted from the light emitting layer 350 may be directed downward and lost by the SPP mode at the interface between the second reflective electrode 323 and the third insulating layer 250. Some of the light emitted from the light emitting layer 350 may be lost by a waveguide mode at the interface between the cathode electrode 370 and the first inorganic encapsulation layer 410. In one or more embodiments, when a capping layer is disposed between the cathode electrode 370 and the encapsulation layer 400, some of the light emitted from the light emitting layer 350 may be lost by the waveguide mode at the interface between the cathode electrode 370 and the capping layer.

However, according to one or more embodiments of the present disclosure, since the surface of the second reflective electrode 323 has corrugation, light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of green light in the second sub-pixel SP2.

Similarly, in the first sub-pixel SP1, since the surface of the first reflective electrode 311 has corrugation due to the first corrugation formation layer 160 disposed under the first reflective electrode 311, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of red light in the first sub-pixel SP1.

Similarly, in the third sub-pixel SP3, since the surface of the third reflective electrode 335 has corrugation due to the first corrugation formation layer 160 disposed under the second insulating layer 200, the light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of blue light in the third sub-pixel SP3.

As the layer is disposed away from the first corrugation formation layer 160, the size or height of corrugation, or surface roughness of the surface may be reduced. The size or height of the corrugation or surface roughness of the upper surface of the second reflective electrode 323 may be smaller than the size or height of the corrugation or surface roughness of the upper surface of the first reflective electrode 311. In addition, the size or height of the corrugation or surface roughness of the upper surface of the third reflective electrode 335 may be smaller than the size or height of the corrugation or surface roughness of the upper surface of the second reflective electrode 323.

Therefore, in the case of the organic light emitting diode display device according to one or more embodiments of the present disclosure shown in FIG. 2, the effect of increasing the light extraction efficiency of red light in the first sub-pixel SP1 may be the greatest, and the effect of increasing the light extraction efficiency of blue light in the third sub-pixel SP3 may be the smallest.

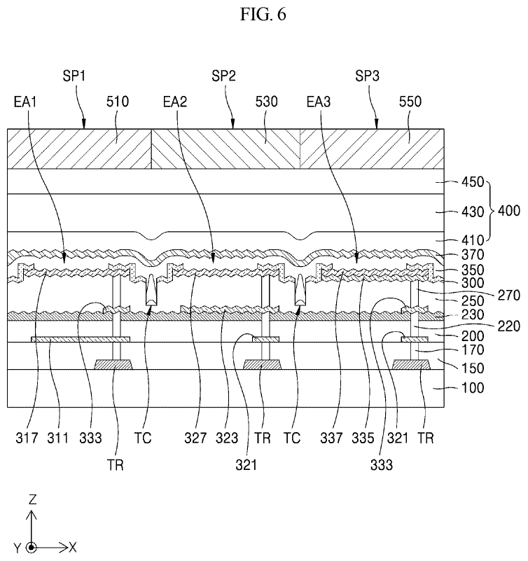

FIG. 6 is a schematic cross-sectional view of the organic light emitting diode display device according to one or more embodiments of the present disclosure.

FIG. 6 corresponds to a cross-sectional view along line 2-2 in FIG. 1. The organic light emitting diode display device shown in FIG. 6 differs from the organic light emitting diode display device shown in FIG. 2 in that the second corrugation formation layer 230 is provided instead of the first corrugation formation layer 160. Therefore, in the following description of the organic light emitting diode display device shown in FIG. 6, only the configuration that differs from that of the organic light emitting diode display device shown in FIG. 2 will be described.

Referring to FIG. 6, the first reflective electrode 311 and the first contact electrodes 321 are directly disposed on the first insulating layer 150, and the second corrugation formation layer 230 is formed on the second insulating layer 200. Therefore, the layers disposed under the second insulating layer 200 do not have corrugation, and lower and upper surfaces of the layers disposed on the second insulating layer 200 may have corrugation. The second corrugation formation layer 230 may be formed of the same material and by the same manufacturing method as the first corrugation formation layer 160.

The lower and upper surfaces of the second reflective electrode 323 and the second contact electrode 333, and the lower and upper surfaces of the third insulating layer 250, which are disposed on the upper surface of the second corrugation formation layer 230, may have corrugation. In addition, the lower and upper surfaces of the first anode electrode 317, the second anode electrode 327, the third reflective electrode 335, and the third anode electrode 337, which are disposed on the third insulating layer 250, may have corrugation. In addition, the lower and upper surfaces of the light emitting layer 350 and the cathode electrode 370 may have corrugation or wrinkle.

According to one or more embodiments of the present disclosure, since the surface of the second reflective electrode 323 has corrugation, light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of green light in the second sub-pixel SP2.

Similarly, in the third sub-pixel SP3, since the surface of the third reflective electrode 335 has corrugation due to the second corrugation formation layer 230 disposed on the second insulating layer 200, the light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of blue light in the third sub-pixel SP3.

On the other hand, since the first reflective electrode 311 has a flat surface in the first sub-pixel SP1, light loss due to the SPP mode cannot be reduced in the first sub-pixel SP1, but the interface between the cathode electrode 370 and the first inorganic encapsulation layer 410 (or the capping layer) has corrugation, light loss due to the waveguide mode can be reduced.

Therefore, it is possible to increase the light extraction efficiency of red light in the first sub-pixel SP1.

As the layer is disposed away from the second corrugation formation layer 230, the size or height of corrugation, or surface roughness of the surface may be reduced. The size or height of the corrugation or surface roughness of the upper surface of the third reflective electrode 335 may be smaller than the size or height of the corrugation or surface roughness of the upper surface of the second reflective electrode 323.

Therefore, in the case of the organic light emitting diode display device according to one or more embodiments of the present disclosure shown in FIG. 6, the effect of increasing the light extraction efficiency of green light in the second sub-pixel SP2 may be the greatest, and the effect of increasing the light extraction efficiency of red light in the first sub-pixel SP1 may be the smallest.

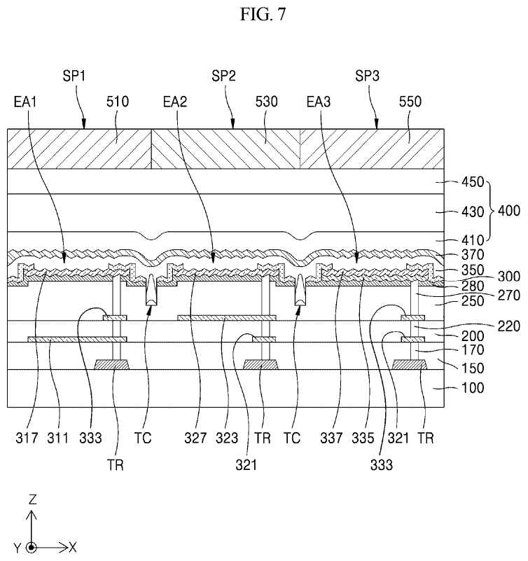

FIG. 7 is a schematic cross-sectional view of the organic light emitting diode display device according to one or more embodiments of the present disclosure.

FIG. 7 corresponds to a cross-sectional view along line 2-2′ in FIG. 1. The organic light emitting diode display device shown in FIG. 7 differs from the organic light emitting diode display device shown in FIG. 2 in that the third corrugation formation layer 280 is provided instead of the first corrugation formation layer 160. Therefore, in the following description of the organic light emitting diode display device shown in FIG. 7, only the configuration that differs from that of the organic light emitting diode display device shown in FIG. 2 will be described.

Referring to FIG. 7, the first reflective electrode 311 and the first contact electrodes 321 are directly disposed on the first insulating layer 150, and the second reflective electrode 323 and the second contact electrode 333 are directly disposed on the second insulating layer 200, and the third corrugation formation layer 280 is disposed on the third insulating layer 250. Therefore, the layers disposed under the third insulating layer 250 do not have corrugation, and lower and upper surfaces of the layers disposed on the third insulating layer 250 may have corrugation. The third corrugation formation layer 280 may be formed of the same material and by the same manufacturing method as the first corrugation formation layer 160.

The lower and upper surfaces of the first anode electrode 317, the second anode electrode 327, the third reflective electrode 335, and the third anode electrode 337, which are disposed on the third corrugation formation layer 280, may have corrugation. In addition, the lower and upper surfaces of the light emitting layer 350 and the cathode electrode 370 may have corrugation or wrinkle.

In the third sub-pixel SP3, since the surface of the third reflective electrode 335 has corrugation due to the third corrugation formation layer 280 disposed on the third insulating layer 250, the light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of blue light in the third sub-pixel SP3.

On the other hand, in the first sub-pixel SP1 and the second sub-pixel SP2, since the first reflective electrode 311 and the second reflective electrode 323 have flat surfaces, light loss due to the SPP mode cannot be reduced, but the interface between the cathode electrode 370 and the first inorganic encapsulation layer 410 (or the capping layer) has corrugation, light loss due to the waveguide mode can be reduced.

Therefore, it is possible to increase the light extraction efficiency of red light in the first sub-pixel SP1 and increase the light extraction efficiency of green light in the second sub-pixel SP2.

Therefore, in the case of the organic light emitting diode display device according to one or more embodiments of the present disclosure shown in FIG. 7, the effect of increasing the light extraction efficiency of blue light in the third sub-pixel SP3 may be the greatest.

The effect of increasing the light extraction efficiency of red light in the first sub-pixel SP1 may be the same as or similar to the effect of increasing the light extraction efficiency of green light in the second sub-pixel SP2.

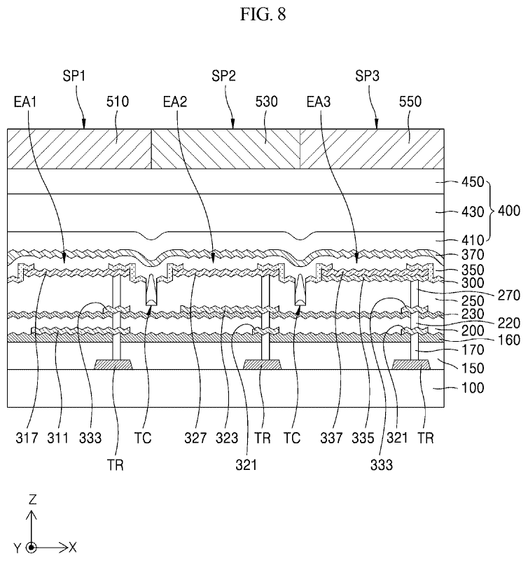

FIG. 8 is a schematic cross-sectional view of the organic light emitting diode display device according to one or more embodiments of the present disclosure.

FIG. 8 corresponds to a cross-sectional view along line 2-2 in FIG. 1. The organic light emitting diode display device shown in FIG. 8 differs from the organic light emitting diode display device shown in FIG. 2 in that both the first corrugation formation layer 160 and the second corrugation formation layer 230 are provided. Therefore, in the following description of the organic light emitting diode display device shown in FIG. 8, only the configuration that differs from that of the organic light emitting diode display device shown in FIG. 2 will be described.

Referring to FIG. 8, the first corrugation formation layer 160 is disposed on the first insulating layer 150, and the second corrugation formation layer 230 is further disposed on the second insulating layer 200.

Therefore, the lower and upper surfaces of the first reflective electrode 311 and the first contact electrodes 321 and the lower and upper surfaces of the second insulating layer 200, which are disposed on the first corrugation formation layer 160, and the lower and upper surfaces of the second reflective electrode 323 and the second contact electrode 333 and the lower and upper surfaces of the third insulating layer 250, which are disposed on the second corrugation formation layer 230, may have corrugation. In addition, the lower and upper surfaces of the first anode electrode 317, the second anode electrode 327, the third reflective electrode 335, and the third anode electrode 337, which are disposed on the third insulating layer 250, may have corrugation. In addition, the lower and upper surfaces of the light emitting layer 350 and the cathode electrode 370, which are disposed on the first to third anode electrodes 317, 327, and 337, may have corrugation or wrinkle.

In the first sub-pixel SP1, since the surface of the first reflective electrode 311 has corrugation due to the first corrugation formation layer 160 disposed under the first reflective electrode 311, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of red light in the first sub-pixel SP1.

Similarly, in the second sub-pixel SP2, since the surface of the second reflective electrode 323 has corrugation due to the second corrugation formation layer 230 disposed under the second reflective electrode 323, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of green light in the second sub-pixel SP2.

Similarly, in the third sub-pixel SP3, since the surface of the third reflective electrode 335 has corrugation due to the second corrugation formation layer 230 disposed on the second insulating layer 200, the light loss due to the SPP mode can be reduced, and in addition, the interface between the cathode electrode 370 and the first inorganic encapsulation layer 410 (or the capping layer) has corrugation, and thus light loss due to the waveguide mode can be reduced.

Therefore, it is possible to increase the light extraction efficiency of blue light in the third sub-pixel SP3.

As the layer is disposed away from the first corrugation formation layer 160, the size or height of corrugation, or surface roughness of the surface may be reduced.

However, by further arranging the second corrugation formation layer 230 on the upper surface of the second insulating layer 200, the second corrugation formation layer 230 may compensate a reduction in the sizes or heights of corrugation or surface roughness of the layers disposed on the second insulating layer 200 as the layers are away from the first corrugation formation layer 160.

Compared to the organic light emitting diode display device shown in FIG. 2, the sizes or heights of corrugation or surface roughness of the layers disposed on the second insulating layer 200 in the second sub-pixel SP2 and the third sub-pixel SP3 of the organic light emitting diode display device shown in FIG. 8 may be greater than the sizes or heights of corrugation or surface roughness of the layers disposed on the second insulating layer 200 in the second sub-pixel SP2 and the third sub-pixel SP3 of the organic light emitting diode display device shown in FIG. 2.

Therefore, in the case of the organic light emitting diode display device according to one or more embodiments of the present disclosure shown in FIG. 8, the effect of increasing the light extraction efficiency of red light in the first sub-pixel SP1 and the effect of increasing the light extraction efficiency of green light in the second sub-pixel SP2 may be greater than the effect of increasing the light extraction efficiency of blue light in the third sub-pixel SP3.

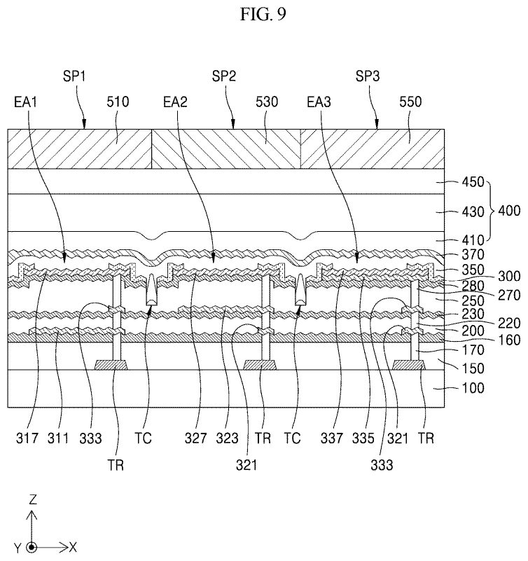

FIG. 9 is a schematic cross-sectional view of the organic light emitting diode display device according to one or more embodiments of the present disclosure.

FIG. 9 corresponds to a cross-sectional view along line 2-2 in FIG. 1. The organic light emitting diode display device shown in FIG. 9 differs from the organic light emitting diode display device shown in FIG. 2 in that all of the first corrugation formation layer 160, the second corrugation formation layer 230, and the third corrugation formation layer 280 are provided. Therefore, in the following description of the organic light emitting diode display device shown in FIG. 9, only the configuration that differs from that of the organic light emitting diode display device shown in FIG. 2 will be described.

Referring to FIG. 9, the first corrugation formation layer 160 is disposed on the first insulating layer 150, the second corrugation formation layer 230 is further disposed on the second insulating layer 200, and the third corrugation formation layer 280 is further disposed on the third insulating layer 250.

Therefore, the lower and upper surfaces of the first reflective electrode 311 and the first contact electrodes 321 and the lower and upper surfaces of the second insulating layer 200, which are disposed on the first corrugation formation layer 160, and the lower and upper surfaces of the second reflective electrode 323 and the second contact electrode 333 and the lower and upper surfaces of the third insulating layer 250, which are disposed on the second corrugation formation layer 230, may have corrugation. In addition, the lower and upper surfaces of the first anode electrode 317, the second anode electrode 327, the third reflective electrode 335, and the third anode electrode 337, which are disposed on the third corrugation formation layer 280, may have corrugation. In addition, the lower and upper surfaces of the light emitting layer 350 and the cathode electrode 370, which are disposed on the first to third anode electrodes 317, 327, and 337, may have corrugation or wrinkle.

In the first sub-pixel SP1, since the surface of the first reflective electrode 311 has corrugation due to the first corrugation formation layer 160 disposed under the first reflective electrode 311, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of red light in the first sub-pixel SP1.

Similarly, in the second sub-pixel SP2, since the surface of the second reflective electrode 323 has corrugation due to the second corrugation formation layer 230 disposed under the second reflective electrode 323, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of green light in the second sub-pixel SP2.

Similarly, in the third sub-pixel SP3, since the surface of the third reflective electrode 335 has corrugation due to the third corrugation formation layer 280 disposed under the third reflective electrode 335, the light loss due to the SPP mode can be reduced, and in addition, since the interface between the cathode electrode 370 and the first inorganic encapsulation layer 410 (or the capping layer) has corrugation, the light loss due to the waveguide mode can be reduced.

Therefore, it is possible to increase the light extraction efficiency of blue light in the third sub-pixel SP3.

As the layer is disposed away from the first corrugation formation layer 160, the size or height of corrugation, or surface roughness of the surface may be reduced.

However, by further arranging the second corrugation formation layer 230 on the upper surface of the second insulating layer 200 and arranging the third corrugation formation layer 280 on the upper surface of the third insulating layer 250, the second corrugation formation layer 230 and the third corrugation formation layer 280 may compensate a reduction in the sizes or heights of corrugation or surface roughness of the layers disposed on the second insulating layer 200 as the layers are away from the first corrugation formation layer 160.

Compared to the organic light emitting diode display device shown in FIG. 2, the sizes or heights of corrugation or surface roughness of the layers disposed on the second insulating layer 200 in the second sub-pixel SP2 and the third sub-pixel SP3 of the organic light emitting diode display device shown in FIG. 9 may be greater than the sizes or heights of corrugation or surface roughness of the layers disposed on the second insulating layer 200 in the second sub-pixel SP2 and the third sub-pixel SP3 of the organic light emitting diode display device shown in FIG. 2. In addition, compared to the organic light emitting diode display device shown in FIG. 8, the sizes or heights of corrugation or surface roughness of the layers disposed on the third insulating layer 250 in the third sub-pixel SP3 of the organic light emitting diode display device shown in FIG. 9 may be greater than the sizes or heights of corrugation or surface roughness of the layers disposed on the third insulating layer 250 in the third sub-pixel SP3 of the organic light emitting diode display device shown in FIG. 8.

Therefore, in the case of the organic light emitting diode display device according to one or more embodiments of the present disclosure shown in FIG. 9, the effect of increasing the light extraction efficiency of red light in the first sub-pixel SP1, the effect of increasing the light extraction efficiency of green light in the second sub-pixel SP2, and the effect of increasing the light extraction efficiency of blue light in the third sub-pixel SP3 may be the same as or similar to each other.

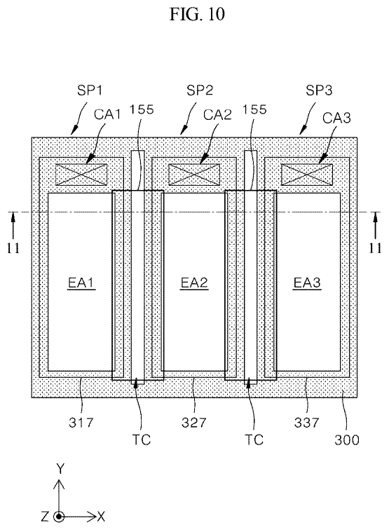

FIG. 10 is a schematic plan view of an organic light emitting diode display device according to one or more embodiments of the present disclosure. In the organic light emitting diode display device according to one or more embodiments of the present disclosure, the plurality of sub-pixels SP1, SP2, and SP3 are disposed in a matrix form, but only three sub-pixels SP1, SP2, and SP3 are shown in FIG. 10.

Referring to FIG. 10, the organic light emitting diode display device according to one or more embodiments of the present disclosure includes the plurality of anode electrodes 317, 327, and 337, the trench TC, a step formation pattern 155, and the bank 300.

For example, the plurality of sub-pixels SP1, SP2, and SP3 arranged in an X-axis direction are provided on the substrate 100.

The plurality of emission areas EA1, EA2, and EA3 corresponding to the plurality of sub-pixels SP1, SP2, and SP3 are provided. The first sub-pixel SP1 has the first emission area EA1, the second sub-pixel SP2 has the second emission area EA2, and the third sub-pixel SP3 has the third emission area EA3.

The plurality of anode electrodes 317, 327, and 337 corresponding to the plurality of sub-pixels SP1, SP2, and SP3 are provided. The first anode electrode 317 may be disposed in the first sub-pixel SP1, the second anode electrode 327 may be formed in the second sub-pixel SP2, and the third anode electrode 337 may be disposed in the third sub-pixel SP3. The first to third anode electrodes 317, 327, and 337 may be spaced apart from each other.

A portion of the first anode electrode 317 not covered by the bank 300 can be defined as the first emission area EA1. The first anode electrode 317 of the first sub-pixel SP1 may be connected to at least one transistor disposed on the substrate 100 through the first contact area CA1.

A portion of the second anode electrode 327 not covered by the bank 300 can be defined as the second emission area EA2. The second anode electrode 327 of the second sub-pixel SP2 may be connected to at least one transistor disposed on the substrate 100 through the second contact area CA2.

A portion of the third anode electrode 337 not covered by the bank 300 can be defined as the third emission area EA3. The third anode electrode 337 of the third sub-pixel SP3 may be connected to at least one transistor disposed on the substrate 100 through the third contact area CA3.

The trench TC extending in the Y-axis direction is formed in boundary areas between the plurality of sub-pixels SP1, SP2, and SP3. The trench TC may be formed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

The length of the trench TC in the Y-axis direction may be greater than lengths of the plurality of emission areas EA1, EA2, and EA3. The length of the trench TC in the Y-axis direction may be greater than or equal to lengths of the plurality of anode electrodes 317, 327, and 337.

The step formation pattern 155 extending in the Y-axis direction is disposed in the boundary areas between the plurality of sub-pixels SP1, SP2, and SP3. The step formation pattern 155 may be disposed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1. The step formation pattern 155 may be formed in the boundary area between the first emission area EA1 and the second emission area EA2, the boundary area between the second emission area EA2 and the third emission area EA3, and the boundary area between the third emission area EA3 and the first emission area EA1.

The step formation pattern 155 may overlap a portion of the trench TC. A width of the step formation pattern 155 in the X-axis direction may be greater than a width of the trench TC.

A length of the step formation pattern 155 in the Y-axis direction may be greater than lengths of the plurality of emission areas EA1, EA2, and EA3. The length of the step formation pattern 155 in the Y-axis direction may be smaller than the lengths of the plurality of anode electrodes 317, 327, and 337. The length of the step formation pattern 155 in the Y-axis direction may be smaller than the trench TC.

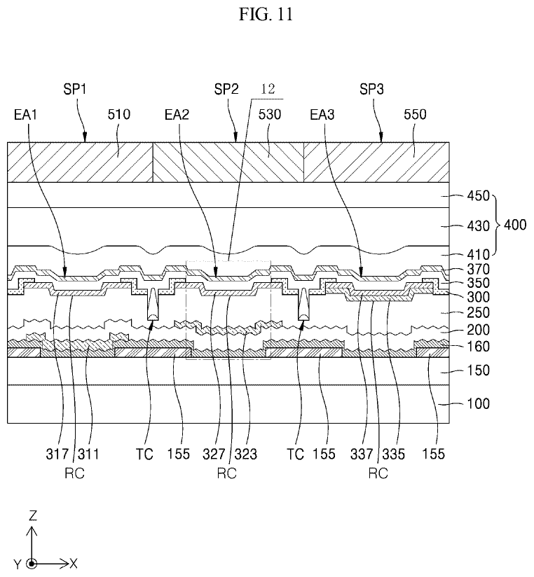

FIG. 11 is a schematic cross-sectional view of the organic light emitting diode display device, which is a cross-sectional view along line 11-11 in FIG. 10 according to one or more embodiments of the present disclosure.

Referring to FIG. 11, the organic light emitting diode display device according to one or more embodiments of the present disclosure may include the substrate 100, the first to third insulating layers 150, 200, and 250, the step formation pattern 155, the corrugation formation layer 160, the first to third reflective electrodes 311, 323, and 335, the first and second contact electrodes (not shown), the first to third anode electrodes 317, 327, and 337, the bank 300, the light emitting layer 350, the cathode electrode 370, the trench TC, the encapsulation layer 400, and the first to third color filters 510, 530, and 550.

The organic light emitting diode display device according to one or more embodiments of the present disclosure may be implemented in a so-called top emission type in which light emitted from the light emitting layer 350 is emitted upward.

For example, the first sub-pixel SP1, the second sub-pixel SP2, and the third sub-pixel SP3 arranged in the X-axis direction are provided on the substrate 100. The first sub-pixel SP1 may emit red light, the second sub-pixel SP2 may emit green light, and the third sub-pixel SP3 may emit blue light. The arrangement order and direction of the sub-pixels SP1, SP2, and SP3 may be changed in any of various ways.

The driving circuit including various signal lines, thin film transistors, capacitors, etc. is provided on the substrate 100 for each of the sub-pixels SP1, SP2, and SP3. The signal lines may include gate lines, data lines, power lines, and reference lines, and transistors may include a switching transistor, a driving transistor and a sensing thin film transistor. For example, the switching transistor, the driving transistor and the sensing thin film transistor may be formed on the substrate 100 using a CMOS process.

The first insulating layer 150 may be disposed on the substrate 100. The first insulating layer 150 may be made of an inorganic insulating material or an organic insulating material. The first insulating layer 150 may cover transistors, various signal lines, capacitors, etc., which are disposed on the substrate 100.

The step formation patterns 155 may be disposed on the first insulating layer 150. The step formation patterns 155 may be disposed in the boundary areas between the first to third sub-pixels SP1, SP2, and SP3.

The first corrugation formation layer 160 covering the step formation patterns 155 may be disposed on the first insulating layer 150. The first corrugation formation layer 160 may cover upper surfaces and side surfaces of the step formation patterns 155.

The first reflective electrode 311 may be disposed on the first corrugation formation layer 160. Since the first reflective electrode 311 is disposed in the first sub-pixel SP1 and the first reflective electrode 311 is formed on the upper surface of the first corrugation formation layer 160 having corrugation, the upper surfaces of the first reflective electrode 311 may also have corrugation.

An edge portion of the first reflective electrode 311 may overlap the step formation pattern 155. Therefore, the edge portion of the first reflective electrode 311 may be located at a higher location than a central portion of the first reflective electrode 311.

The first reflective electrode 311 may be made of a metal material with high reflectivity, such as silver (Ag), a silver alloy, aluminum (Al), or an aluminum alloy.

The second insulating layer 200 may be disposed on the first corrugation formation layer 160, and the second insulating layer 200 may cover the upper surface and side surfaces of the first reflective electrode 311. Since the second insulating layer 200 is formed on the upper surface of the first corrugation formation layer 160 having corrugation and the first reflective electrode 311 having corrugation, the upper surface of the second insulating layer 200 may also have corrugation.

The second insulating layer 200 may be made of an inorganic insulating material or an organic insulating material.

The second reflective electrode 323 may be disposed on the second insulating layer 200. Since the second reflective electrode 323 is disposed in the second sub-pixel SP2 and the second reflective electrode 323 is formed on the upper surface of the second insulating layer 200 having corrugation, the upper surface of the second reflective electrode 323 may also have corrugation.

However, since the second reflective electrode 323 is disposed further away from the first corrugation formation layer 160 than the first reflective electrode 311, the size or height of corrugation, or surface roughness of the upper surface of the second reflective electrode 323 may be smaller than the size or height of corrugation, or surface roughness of the upper surface of the first reflective electrode 311.

An edge portion of the second reflective electrode 323 may overlap the step formation pattern 155. Therefore, the edge portion of the second reflective electrode 323 may be located at a higher location than a central portion of the second reflective electrode 323.

The second reflective electrode 323 may be made of a metal material with high reflectivity, such as silver (Ag), a silver alloy, aluminum (Al), or an aluminum alloy.

The third insulating layer 250 may be disposed on the second insulating layer 200, and the third insulating layer 250 may cover the upper surface and side surfaces of the second reflective electrode 323.

Since the third insulating layer 250 is disposed away from the first corrugation formation layer 160, the upper surface of the third insulating layer 250 may not have corrugation. However, due to the step formation patterns 155 disposed in the boundary areas between the first to third sub-pixels SP1, SP2, and SP3, the upper surface of the third insulating layer 250 may include recesses RC located in the first to third emission areas EA1, EA2, and EA3 of the first to third sub-pixels SP1, SP2, and SP3.

The third insulating layer 250 may be made of an inorganic insulating material or an organic insulating material.

The first anode electrode 317, the second anode electrode 327, the third reflective electrode 335, the third anode electrode 337 may be disposed on the third insulating layer 250. The first anode electrode 317 may be disposed in the first sub-pixel SP1, the second anode electrode 327 may be disposed in the second sub-pixel SP2, and the third reflective electrode 335 and the third anode electrode 337 may be disposed in the third sub-pixel SP3.

The third reflective electrode 335 and the third anode electrode 337 may be in contact with each other in the third sub-pixel SP3.

Since the first anode electrode 317, the second anode electrode 327, the third reflective electrode 335, and the third anode electrode 337 are formed on the upper surface of the third insulating layer 250 having the recesses RC, the first anode electrode 317, the second anode electrode 327, the third reflective electrode 335, and the third anode electrode 337 may each have the recess RC.

The third reflective electrode 335 may be made of a metal material with high reflectivity, such as silver (Ag), a silver alloy, aluminum (Al), or an aluminum alloy. The first to third anode electrodes 317, 327, and 337 may be made of a transparent conductive material such as ITO or IZO that may transmit light.

The first to third anode electrodes 317, 327, and 337 may each be electrically connected to the source terminal or drain terminal of the driving transistor disposed on the substrate 100.

The bank 300 may be disposed to cover the edge areas of the first to third anode electrodes 317, 327, and 337 on the third insulating layer 250. Portions of upper surfaces of the first to third anode electrodes 317, 327, and 337 exposed without covered by the bank 300 become the first to third emission areas EA1, EA2, and EA3. The bank 300 may be made of an inorganic insulating material. In one or more embodiments, the bank 300 may be made of an organic insulating material.

The trench TC having a concave structure is formed in the bank 300 and the third insulating layer 250. The trench TC may pass through the bank 300 in the boundary areas between the sub-pixels SP1, SP2, and SP3 and extend to a predetermined area of the third insulating layer 250. Therefore, the trench TC may be formed through a process of removing the bank 300 and the predetermined area of the third insulating layer 250. In one or more embodiments, the trench TC may extend to the inside of the second insulating layer 200 under the third insulating layer 250.

The trench TC is used to disconnect at least a portion of the light emitting layer 350. By disconnecting the at least a portion of the light emitting layer 350 in the trench TC, it is possible to prevent charges from moving between the neighboring sub-pixels SP1, SP2, and SP3 through the light emitting layer 350, thereby preventing the generation of a leakage current between the neighboring sub-pixels SP1, SP2, and SP3.

The light emitting layer 350 may be disposed in the emission areas EA1, EA2, and EA3 of the sub-pixels SP1, SP2, and SP3 and the boundary areas between the sub-pixels SP1, SP2, and SP3. The light emitting layer 350 is disposed on the first anode electrodes 317, 327, and 337 and the bank 300. In addition, the light emitting layer 350 may also be disposed inside and above the trench TC.

The light emitting layer 350 may be provided to emit white (W) light. To this end, the light emitting layer 350 may include a plurality of stacks that emit light of different colors.

The light emitting layer 350 may be disposed in the concave shape in the first to third emission areas EA1, EA2, and EA3 of the first to third sub-pixels SP1, SP2, and SP3.

The cathode electrode 370 is formed on the light emitting layer 350. Like the light emitting layer 350, the cathode electrode 370 may also be disposed in the emission areas EA1, EA2, and EA3 of the sub-pixels SP1, SP2, and SP3 and the boundary areas between the sub-pixels SP1, SP2, and SP3. The cathode electrode 370 is a common layer and may also be formed on the bank 300 and the trench TC.

The cathode electrode 370 may be disposed in the concave shape in the first to third emission areas EA1, EA2, and EA3 of the first to third sub-pixels SP1, SP2, and SP3.

The cathode electrode 370 may be made of a semi-transparent conductive material. The cathode electrode 370 may be made of a semi-transparent metal material such as magnesium (Mg), silver (Ag), or an alloy of magnesium (Mg) and silver (Ag). The cathode electrode 370 may be formed in the form of a thin film having the thickness of several nanometers to tens of nanometers. Therefore, it is possible to obtain the micro cavity effect as light is repeatedly reflected and re-reflected between the cathode electrode 370 and the first to third reflective electrodes 311, 323, and 335.

According to one or more embodiments of the present disclosure, since the first distance between the first reflective electrode 311 and the cathode electrode 370 in the first sub-pixel SP1, the second distance between the second reflective electrode 323 and the cathode electrode 370 in the second sub-pixel SP2, and the third distance between the third reflective electrode 335 and the cathode electrode 370 in the third sub-pixel SP3 may all be configured differently, it is possible to increase light extraction efficiency of light of different colors, such as red, green, and blue light in the sub-pixels SP1, SP2, and SP3 by the micro cavity effect.

In addition, according to one or more embodiments of the present disclosure, the light emitting layer 350 and the cathode electrode 370 are disposed in the concave shape in the first to third emission areas EA1, EA2, and EA3 of the first to third sub-pixels SP1, SP2, and SP3, it is possible to increase light emission in the front direction.

The encapsulation layer 400 is formed on the cathode electrode 370 to prevent the permeation of external moisture into the light emitting layer 350. The encapsulation layer 400 may include a first inorganic encapsulation layer 410 disposed on the cathode electrode 370, an organic encapsulation layer 430 disposed on the first inorganic encapsulation layer 410, and a second inorganic encapsulation layer 450 disposed on the organic encapsulation layer 430.

The color filters 510, 530, and 550 may be disposed on the encapsulation layer 400. The red color filter 510 overlapping the first emission area EA1 may be provided in the first sub-pixel SP1, the green color filter 530 overlapping the second emission area EA2 may be provided in the second sub-pixel SP2, and the blue color filter 550 overlapping the third emission area EA3 may be provided in the third sub-pixel SP3.

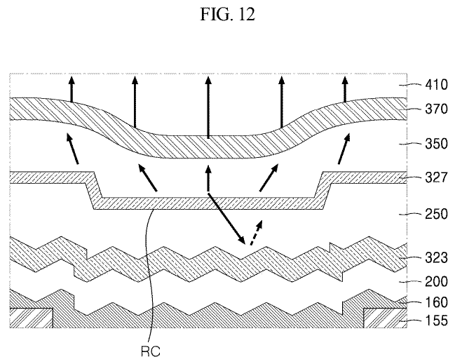

FIG. 12 is an enlarged view of area 12 in FIG. 11 according to one or more embodiments of the present disclosure. FIG. 12 is an enlarged view of a portion of the second sub-pixel SP2 to describe an increase in light extraction efficiency in the organic light emitting diode display device according to one or more embodiments of the present disclosure.

Referring to FIG. 12, by arranging the step formation patterns 155 on the first insulating layer 150 in the boundary areas between the first to third sub-pixels SP1, SP2, and SP3 and arranging the first corrugation formation layer 160 covering the step formation patterns 155 under the second insulating layer 200, the lower and upper surfaces of the second insulating layer 200 and the lower and upper surfaces of the second reflective electrode 323 may have corrugation, and the third insulating layer 250, the second anode electrode 327, the light emitting layer 350, and the cathode electrode 370 may be disposed in a concave shape in the first to third emission areas EA1, EA2, and EA3 of the first to third sub-pixels SP1, SP2, and SP3.

According to one or more embodiments of the present disclosure, since the surface of the second reflective electrode 323 has corrugation, the light loss due to the SPP mode can be reduced, and in addition, since the upper surfaces of the light emitting layer 350 and the cathode electrode 370 have the concave shape in the second emission area EA2, it is possible to increase light emission in the front direction.

Therefore, it is possible to increase the light extraction efficiency of green light in the second sub-pixel SP2.

Similarly, in the first sub-pixel SP1, since the surface of the first reflective electrode 311 has corrugation due to the first corrugation formation layer 160 disposed under the first reflective electrode 311, the light loss due to the SPP mode can be reduced, and in addition, since the upper surfaces of the light emitting layer 350 and the cathode electrode 370 have the concave shape in the first emission area EA1 due to the step formation patterns 155, it is possible to increase the forward emission.

Therefore, it is possible to increase the light extraction efficiency of red light in the first sub-pixel SP1.

Similarly, in the third sub-pixel SP3, since the interface between the light emitting layer 350 and the cathode electrode 370 has the concave shape in the third emission area EA3 due to the step formation patterns 155, it is possible to increase the forward emission.

Therefore, it is possible to increase the light extraction efficiency of blue light in the third sub-pixel SP3.

The step formation patterns 155 disposed on the first insulating layer 150 in the boundary areas between the first to third sub-pixels SP1, SP2, and SP3 are also used in the embodiments shown in FIGS. 6 to 9.

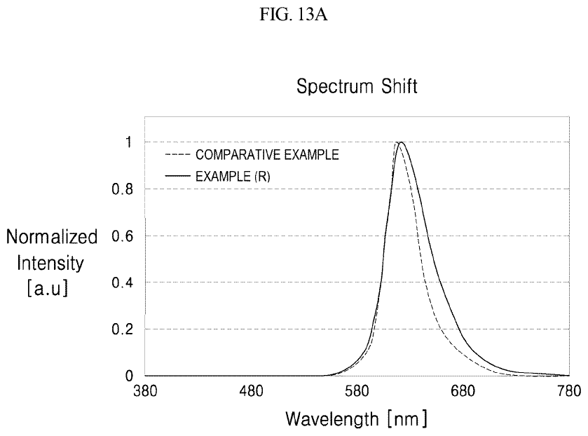

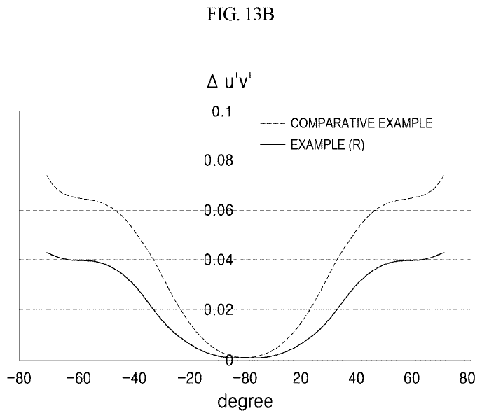

FIGS. 13A and 13B are views showing the spectrum and Δu‘v’ values, respectively according to a viewing angle of light emitted from a first sub-pixel (red sub-pixel) of the organic light emitting diode display device according to one or more embodiments of the present disclosure. In FIGS. 13A and 13B, Example (R) is, for example, a case where the first corrugation formation layer 160 is provided immediately under the first reflective electrode 311 as in the embodiment shown in FIG. 2, and Comparative Example is a case where no corrugation formation layer is provided.

Referring to FIGS. 13A and 13B, in the Example (R), compared to the Comparative Example, the peak of light emitted from the red sub-pixel tends to broaden toward long wavelengths and the Δu‘v’ value tends to decrease. In the Example (R), it can be seen that the color change of red light according to a change in viewing angle is less compared to the Comparative Example.

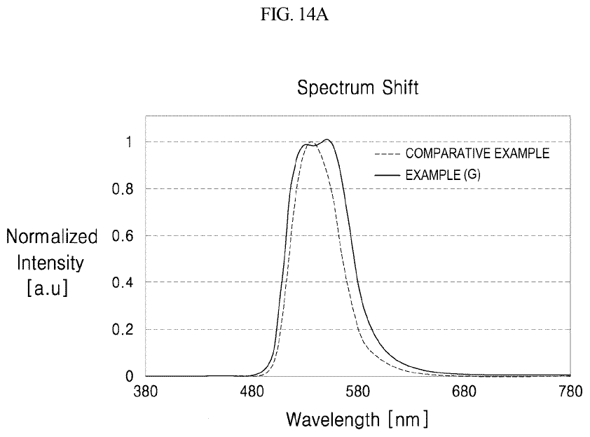

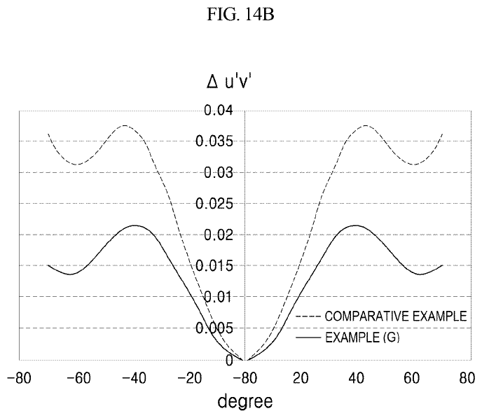

FIGS. 14A and 14B are views showing the spectrum and Δu‘v’ values, respectively according to a viewing angle of light emitted from a second sub-pixel (green sub-pixel) of the organic light emitting diode display device according to one or more embodiments of the present disclosure. In FIGS. 14A and 14B, Example (G) is, for example, a case where the second corrugation formation layer 230 is provided immediately under the second reflective electrode 323 as in the embodiment shown in FIG. 6, and Comparative Example is a case where no corrugation formation layer is provided.

Referring to FIGS. 14A and 14B, in the Example (G), compared to Comparative Example, the peak of light emitted from the green sub-pixel tends to broaden toward long wavelengths and the Δu‘v’ value tends to decrease. In the Example (G), it can be seen that the color change of green light according to a change in viewing angle is less compared to the Comparative Example.

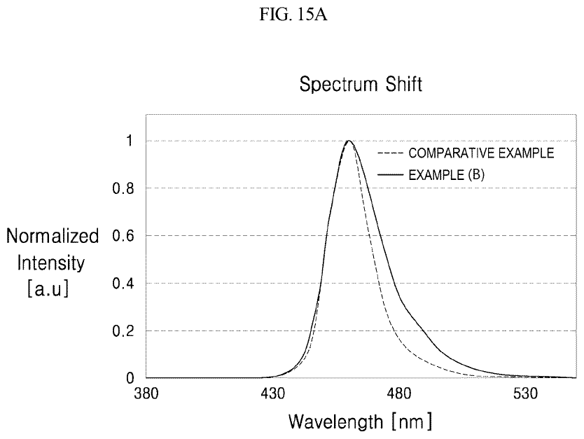

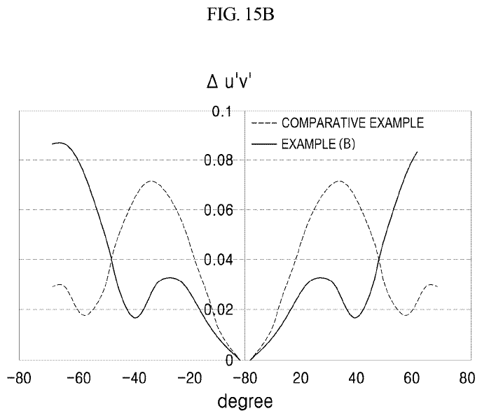

FIGS. 15A and 15B are views showing the spectrum and Δu‘v’ values, respectively according to a viewing angle of light emitted from a third sub-pixel (blue sub-pixel) of the organic light emitting diode display device according to one or more embodiments of the present disclosure. In FIGS. 15A and 15B, Example (B) is, for example, a case where the third corrugation formation layer 280 is provided immediately under the third reflective electrode 335 as in the embodiment shown in FIG. 7, and Comparative Example is a case where no corrugation formation layer is provided.

Referring to FIGS. 15A and 15B, in the Example (B), compared to Comparative Example, the peak of light emitted from the blue sub-pixel tends to broaden toward long wavelengths and the Δu‘v’ value tends to decrease. In the Example (B), it can be seen that the color change according to the viewing angle is less compared to the Comparative Example.

According to the embodiments of the present disclosure, it is possible to increase the light extraction efficiency of the organic light emitting diode display device and increase color uniformity according to the change in viewing angle.

In addition, according to the embodiments of the present disclosure, since the peak of the light emitted from the sub-pixel tends to broaden toward the long wavelength by forming the corrugation formation layer under the reflective electrode, the color of light emitted from at least one of the first to third sub-pixels may be adjusted by selectively forming at least one of the first to third corrugation formation layers under at least one of the first to third reflective electrodes as needed.

For example, to implement deep red by moving the light emitting wavelength of the red emitting layer EML(R) in the light emitting layer 350 to a longer wavelength, the first corrugation formation layer 160 may be provided under the first reflective electrode 311.

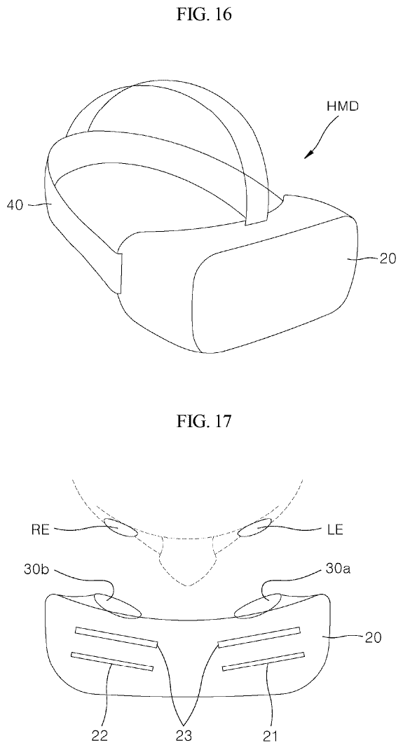

FIGS. 16 to 18 show a head mounted display device according to one or more embodiments of the present disclosure.

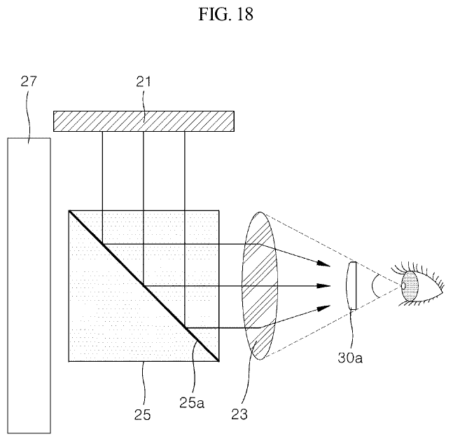

FIG. 16 is a schematic perspective view of a head mounted display device according to one or more embodiments of the present disclosure, FIG. 17 is a view schematically showing a head mounted display device in which virtual reality (VR) is implemented according to one or more embodiments of the present disclosure, and FIG. 18 is a view schematically showing a head mounted display device in which augmented reality (AR) is implemented according to one or more embodiments of the present disclosure.

Referring to FIG. 16, the head mounted display device according to one or more embodiments of the present disclosure includes a storage case 20 and a head mounting band 40.

The storage case 20 stores components, such as a display device, a lens array, and an eyepiece, therein.

The head mounting band 40 is fixed to the storage case 20. An example in which the head mounting band 40 is formed to surround an upper surface and side surfaces of the user's head is described, but the present disclosure is not limited thereto. The head mounting band 40 is used to fix the head mounted display device to the user's head and may be replaced with a structure in the form of a glasses frame or a helmet.

Referring to FIG. 17, the head mounted display device in which the VR is implemented includes a left-eye display device 21, a right-eye display device 22, a lens array 23, a left-eye eyepiece 30a, and a right-eye eyepiece 30b.

The left-eye display device 21, the right-eye display device 22, the lens array 23, the left-eye eyepiece 30a, and right-eye eyepiece 30b are stored in the storage case 20.

The left-eye display device 21 and the right-eye display device 22 may display the same image, and in this case, the user may view 2D images. Alternatively, the left-eye display device 21 may display left-eye images, and the right-eye display device 22 may display right-eye images, and in this case, the user may view three-dimensional images. The left-eye display device 21 and the right-eye display device 22 may each be provided as the above-described organic light emitting diode display device according to FIGS. 1 to 12.

The lens array 23 may be spaced apart from each of the left-eye eyepiece 30a and the left-eye display device 21 and provided between the left-eye eyepiece 30a and the left-eye display device 21. In other words, the lens array 23 may be located in front of the left-eye eyepiece 30a and behind the left-eye display device 21. In addition, the lens array 23 may be spaced apart from each of the right-eye eyepiece 30b and the right-eye display device 22 and provided between the right-eye eyepiece 30b and the right-eye display device 22. In other words, the lens array 23 may be located in front of the right-eye eyepiece 30b and behind the right-eye display device 22.

The lens array 23 may be a micro lens array. The lens array 23 may be replaced with a pin hole array. Due to the lens array 23, images displayed on the left-eye display device 21 and the right-eye display device 22 may be enlarged and visible to the user.

The user's left eye LE may be located behind the left-eye eyepiece 30a, and the user's right eye RE may be located behind the right-eye eyepiece 30b.

Referring to FIG. 18, the head mounted display device in which the AR is implemented includes the left-eye display device 21, the lens array 23, the left-eye eyepiece 30a, a transmission reflector 25, and a transmission window 27. In FIG. 18, only a configuration of the left-eye side is shown for convenience, and a configuration of the right-eye side is also the same or similar to that of the left-eye side.

The left-eye display device 21, the lens array 23, the left-eye eyepiece 30a, the transmission reflector 25, and the transmission window 27 are stored in the storage case 20.

The left-eye display device 21 may be disposed at one side, for example, an upper side of the transmission reflector 25 without blocking the transmission window 27. Therefore, the left-eye display device 21 may provide images to the transmission reflector 25 without blocking an external background visible through the transmission window 27.

The left-eye display device 21 may be provided as the above-described organic light emitting diode display device according to FIGS. 1 to 12.

The lens array 23 may be provided between the left-eye eyepiece 30a and the transmission reflector 25.

The user's left eye is located behind the left-eye eyepiece 30a.

The transmission reflector 25 is disposed between the lens array 23 and the transmission window 27. The transmission reflector 25 may include a reflective surface 25a for transmitting some of light and reflecting others of the light. The reflective surface 25a includes a semi-transparent metal film. The semi-transparent metal film may be made of a semi-transparent metal material such as magnesium (Mg), silver (Ag), or an alloy of magnesium (Mg) and silver (Ag). The reflective surface 25a is formed so that the images displayed on the left-eye display device 21 proceed to the lens array 23.

Therefore, the user may view both the external background visible through the transmission window 27 and the images displayed by the left-eye display device 21. In other words, since the user may view the real background and the virtual image as one image by allowing the real background and the virtual image to overlap each other, the AR can be implemented.

A display device and a head mounted display device according to embodiments of the present disclosure may be described as follows.

An organic light emitting diode display device according to one or more embodiments of the present disclosure includes a substrate including a first sub-pixel, a second sub-pixel, and a third sub-pixel, a first insulating layer disposed on the substrate, a first reflective electrode disposed on the first insulating layer in the first sub-pixel, a second insulating layer covering the first reflective electrode and disposed on the first insulating layer, a second reflective electrode disposed on the second insulating layer in the second sub-pixel, a third insulating layer covering the second reflective electrode and disposed on the second insulating layer, a third reflective electrode disposed on the third insulating layer in the third sub-pixel, and at least one corrugation formation layer disposed under at least one of the first reflective electrode, the second reflective electrode, and the third reflective electrode and having a corrugated surface.

According to one or more embodiments of the present disclosure, the at least one corrugation formation layer may be made of tetraphenylethylene.

According to one or more embodiments of the present disclosure, the at least one of the first reflective electrode, the second reflective electrode, and the third reflective electrode may have a corrugated upper surface.

According to one or more embodiments of the present disclosure, the organic light emitting diode display device may further include a first anode electrode disposed on the third insulating layer in the first sub-pixel, a second anode electrode disposed on the third insulating layer in the second sub-pixel, a third anode electrode disposed on the third reflective electrode in the third sub-pixel, light emitting layers disposed on the first anode electrode, the second anode electrode, and the third anode electrode, and a cathode electrode disposed on the light emitting layer, in which lower and upper surfaces of the light emitting layer and lower and upper surfaces of the cathode electrode may have corrugation.

According to one or more embodiments of the present disclosure, the organic light emitting diode display device may include a first corrugation formation layer disposed between the first insulating layer and the first reflective electrode.

According to one or more embodiments of the present disclosure, the organic light emitting diode display device may include a second corrugation formation layer disposed between the second insulating layer and the second reflective electrode.

According to one or more embodiments of the present disclosure, the organic light emitting diode display device may include a third corrugation formation layer disposed between the third insulating layer and the third reflective electrode.

According to one or more embodiments of the present disclosure, the organic light emitting diode display device may include a first corrugation formation layer disposed between the first insulating layer and the first reflective electrode, and include a second corrugation formation layer disposed between the second insulating layer and the second reflective electrode.

According to one or more embodiments of the present disclosure, the organic light emitting diode display device may include a first corrugation formation layer disposed between the first insulating layer and the first reflective electrode, a second corrugation formation layer disposed between the second insulating layer and the second reflective electrode, and a third corrugation formation layer disposed between the third insulating layer and the third reflective electrode.

According to one or more embodiments of the present disclosure, the organic light emitting diode display device may further include step formation patterns disposed on the first insulating layer and disposed in boundary areas between the first to third sub-pixels, and the at least one corrugation formation layer may cover the step formation patterns and may be disposed between the first insulating layer and the first reflective electrode.

According to one or more embodiments of the present disclosure, edge portions of the first to third reflective electrodes may overlap the step formation patterns.

According to one or more embodiments of the present disclosure, the third insulating layer may include recesses located in the first to third sub-pixels.

According to one or more embodiments of the present disclosure, the organic light emitting diode display device may further include a light emitting layer disposed on the third insulating layer, and a cathode electrode disposed on the light emitting layer, and the light emitting layer and the cathode electrode may also have recesses.

According to one or more embodiments of the present disclosure, the organic light emitting diode display device may further include trenches disposed in the third insulating layer and disposed in boundary areas between the first to third sub-pixels, and widths of the step formation patterns may be greater than widths of the trenches.

A head mounted display device according to one or more embodiments of the present disclosure includes left-eye and right-eye eyepieces, and left-eye and right-eye display devices for providing images to the left-eye and right-eye eyepieces, in which the left-eye and right-eye display devices each includes a substrate including a first sub-pixel, a second sub-pixel, and a third sub-pixel, a first insulating layer disposed on the substrate, a first reflective electrode disposed on the first insulating layer in the first sub-pixel, a second insulating layer covering the first reflective electrode and disposed on the first insulating layer, a second reflective electrode disposed on the second insulating layer in the second sub-pixel, a third insulating layer covering the second reflective electrode and disposed on the second insulating layer, and a third reflective electrode disposed on the third insulating layer in the third sub-pixel, and includes at least one corrugation formation layer disposed under at least one of the first reflective electrode, the second reflective electrode, and the third reflective electrode and having a corrugated surface.

According to the embodiments of the present disclosure, since the first distance between the first reflective electrode and the cathode electrode in the first sub-pixel, the second distance between the second reflective electrode and the cathode electrode in the second sub-pixel, and the third distance between the third reflective electrode and the cathode electrode in the third sub-pixel may all be configured differently, it is possible to increase light extraction efficiency of light of different colors, such as red, green, and blue light in the sub-pixels of the organic light emitting diode display device by the micro cavity effect.

In addition, according to the embodiments of the present disclosure, since the reflective electrode has the corrugated surface, it is possible to reduce the light loss due to a surface plasmon polariton (SPP) mode, and in addition, since the interface between the cathode electrode and the first inorganic encapsulation layer has corrugation, it is possible to reduce the light loss due to the waveguide mode.

Therefore, it is possible to increase light extraction efficiency from the sub-pixels of the organic light emitting diode display device.

In addition, according to the embodiments of the present disclosure, it is possible to increase the light extraction efficiency of the organic light emitting diode display device and increase color uniformity according to the change in viewing angle.

In addition, according to the embodiments of the present disclosure, since the light emitting layer and the cathode electrode are disposed in the concave shape in the emission area of the sub-pixel, it is possible to increase light emission in the front direction of the organic light emitting diode display device.

In addition, it is possible to implement the low-power driving of the organic light emitting diode display device by increasing the light extraction efficiency. In other words, it is possible to reduce the consumed power of the organic light emitting diode display device by increasing the light extraction efficiency.

The effects of the present disclosure are not limited to the above-described effects, and other effects that are not mentioned will be able to be clearly understood by those skilled in the art from the following description.

Although the embodiments of the present disclosure have been described in detail with reference to the accompanying drawings, the present disclosure is not necessarily limited to these embodiments, and various modifications may be carried out without departing from the technical spirit of the present disclosure. Therefore, the embodiments disclosed in the present disclosure are not intended to limit the technical spirit of the present disclosure, but is intended to describe the same, and the scope of the technical spirit of the present disclosure is not limited by these embodiments.

What is claimed is:

1. An organic light emitting diode display device, comprising:
a substrate including a first sub-pixel, a second sub-pixel, and a third sub-pixel;
a first insulating layer on the substrate;
a first reflective electrode on the first insulating layer in the first sub-pixel;
a second insulating layer covering the first reflective electrode and on the first insulating layer;
a second reflective electrode on the second insulating layer in the second sub-pixel;
a third insulating layer covering the second reflective electrode and on the second insulating layer;
a third reflective electrode on the third insulating layer in the third sub-pixel; and
at least one corrugation formation layer under at least one of the first reflective electrode, the second reflective electrode, and the third reflective electrode, the at least one corrugation formation layer having a corrugated surface.

2. The organic light emitting diode display device of claim 1, wherein the at least one corrugation formation layer includes tetraphenylethylene.

3. The organic light emitting diode display device of claim 1, wherein at least one of the first reflective electrode, the second reflective electrode, and the third reflective electrode has a corrugated upper surface.

4. The organic light emitting diode display device of claim 1, further comprising:
a first anode electrode on the third insulating layer in the first sub-pixel;
a second anode electrode on the third insulating layer in the second sub-pixel;
a third anode electrode on the third reflective electrode in the third sub-pixel;
a light emitting layer on the first anode electrode, the second anode electrode, and the third anode electrode; and
a cathode electrode on the light emitting layer,
wherein each of a lower surface and an upper surface of the light emitting layer has corrugation, and
wherein each of a lower surface and an upper surface of the cathode electrode has corrugation.

5. The organic light emitting diode display device of claim 1, wherein the at least one corrugation formation layer comprises a corrugation formation layer between the first insulating layer and the first reflective electrode.

6. The organic light emitting diode display device of claim 1, wherein the at least one corrugation formation layer comprises a corrugation formation layer between the second insulating layer and the second reflective electrode.

7. The organic light emitting diode display device of claim 1, wherein the at least one corrugation formation layer comprises a corrugation formation layer between the third insulating layer and the third reflective electrode.

8. The organic light emitting diode display device of claim 1, wherein the at least one corrugation formation layer comprises:
a first corrugation formation layer between the first insulating layer and the first reflective electrode; and
a second corrugation formation layer between the second insulating layer and the second reflective electrode.

9. The organic light emitting diode display device of claim 1, wherein the at least one corrugation formation layer comprises:
a first corrugation formation layer between the first insulating layer and the first reflective electrode;
a second corrugation formation layer between the second insulating layer and the second reflective electrode; and
a third corrugation formation layer between the third insulating layer and the third reflective electrode.

10. The organic light emitting diode display device of claim 1, further comprising:
a plurality of step formation patterns on the first insulating layer and in boundary areas between the first sub-pixel, the second sub-pixel, and the third sub-pixel,
wherein the at least one corrugation formation layers cover the plurality of step formation patterns, and
wherein the at least one corrugation formation layers are between the first insulating layer and the first reflective electrode.

11. The organic light emitting diode display device of claim 10, wherein each of the first reflective electrode, the second reflective electrode, and the third reflective electrode includes a plurality of edge portions that overlap the plurality of step formation patterns.

12. The organic light emitting diode display device of claim 10, wherein the third insulating layer includes a plurality of recesses located in the first sub-pixel, the second sub-pixel, and the third sub-pixel.

13. The organic light emitting diode display device of claim 12, further comprising:
a light emitting layer on the third insulating layer; and
a cathode electrode on the light emitting layer,
wherein the light emitting layer and the cathode electrode include one or more recesses.

14. The organic light emitting diode display device of claim 10, further comprising:
a plurality of trenches on the third insulating layer and in boundary areas between the first sub-pixel, the second sub-pixel, and the third sub-pixel,
wherein a width of each of the plurality of step formation patterns is greater than a width of each of the plurality of trenches.

15. A head mounted display device, comprising:
a left-eye eyepiece;
a right-eye eyepiece;
a left-eye display device configured to provide a first image to the left-eye eyepiece, wherein the left-eye display device is the organic light emitting diode display device of claim 1; and
a right-eye display device configured to provide a second image to the right-eye eyepiece, wherein the right-eye eyepiece is the organic light emitting diode display device of claim 1.
